(19) United States
(12) Patent Application Publication
(10) Pub. No.: US 2015/0206547 A1
(43) Pub. Date: Jul. 23, 2015

(54) PERPENDICULAR MAGNETIC RECORDING MEDIUM, METHOD OF MANUFACTURING THE SAME, AND MAGNETIC RECORDING/REPRODUCTION APPARATUS

(71) Applicant: KABUSHIKI KAISHA TOSHIBA, Minato-ku (JP)

(72) Inventors: Takeshi IWASAKI, Inagi-shi (JP); Akira WATANABE, Kawasaki-shi (JP)

(73) Assignee: KABUSHIKI KAISHA TOSHIBA, Minato-ku (JP)

(21) Appl. No.: 14/208,894

(22) Filed: Mar. 13, 2014

(30) Foreign Application Priority Data
Jan. 17, 2014 (JP) 2014-007037

(51) Int. Cl. G11B 5/667; C30B 23/08; G11B 5/84; G11B 5/851; G11B 5/738

(52) U.S. Cl. CPC G11B 5/667; G11B 5/851; G11B 5/738; G11B 5/8404; C30B 23/08

(57) ABSTRACT

A perpendicular magnetic recording medium according to an embodiment includes a soft underlayer, an orientation control layer mainly containing Ni having a face-centered cubic structure, a grain size control layer including a plurality of metal oxide posts having a pitch dispersion of 15% or less and crystal grains having grown in a region defined by the plurality of metal oxide posts, and having a hexagonal close-packed structure or face-centered cubic structure, and a perpendicular magnetic recording layer, formed in this order on a substrate.

### CROSS-REFERENCE TO RELATED APPLICATIONS

This application is based upon and claims the benefit of priority from Japanese Patent Application No. 2014-007037, filed Jan. 17, 2014, the entire contents of which are incorporated herein by reference.

### FIELD

Embodiments described herein relate generally to a perpendicular magnetic recording medium, a method of manufacturing the perpendicular magnetic recording medium, and a magnetic recording/reproduction apparatus.

### BACKGROUND

Magnetic recording devices (HDDs) mainly used in computers and capable of information recording and reproduction are used in various fields such as household video decks, audio apparatuses, and automobile navigation systems for reasons such as large capacities, low costs, high data access speeds, and high data retention reliability. As the use range of the HDDs expands, demands for increasing the storage capacity are also increasing. Recently, therefore, the development of high-density HDDs is more and more extensively made.

A so-called perpendicular magnetic recording method is recently mainly used as a magnetic recording method for presently commercially available HDDs. In the perpendicular magnetic recording method, magnetic crystal grains forming a magnetic recording layer for recording information have the axis of easy magnetization in a direction perpendicular to a substrate. Accordingly, the influence of a demagnetizing field between recording bits is small even when the density is increased, and the medium is magnetostatically stable even at a high density. The perpendicular magnetic recording medium generally includes a substrate, a soft underlayer (SUL) for concentrating a magnetic flux generated from a magnetic head during recording, a nonmagnetic seed layer and/or nonmagnetic underlayer for orienting magnetic crystal grains of a perpendicular magnetic recording layer in the (00.1) plane, and reducing the orientation dispersion, the perpendicular magnetic recording layer containing a hard magnetic material, and a protective layer for protecting the surface of the perpendicular magnetic recording layer.

A granular type recording layer having a so-called granular structure in which magnetic crystal grains are surrounded by a grain boundary region made of a nonmagnetic substance has a structure in which the magnetic crystal grains are two-dimensionally physically isolated by the nonmagnetic grain boundary region. This reduces the magnetic exchange interaction acting between the magnetic grains. This makes it possible to reduce the transition noise in the recording/reproduction characteristics, and decrease the limit bit size. On the other hand, the exchange interaction between the grains is reduced in the granular type recording layer. This often increases the dispersion of a magnetic switching field, which is caused by the composition of the grain and the dispersion of the grain size. As a consequence, the transition noise and jitter noise often increase in the recording/reproduction characteristics.

Also, the lower limit of the recording bit size strongly depends on the magnetic crystal grain size of the granular type recording layer. To increase the recording density of the HDD, therefore, it is necessary to decrease the grain size of the granular type recording layer. As a method of decreasing the grain size of the granular type recording layer, there is a method of forming an underlayer having a very small crystal grain size, thereby decreasing the grain size of the granular type recording layer stacked on the underlayer. To decrease the grain size of the underlayer, it is possible to, e.g., improve a nonmagnetic seed layer, or granularize the underlayer.

### BRIEF DESCRIPTION OF THE DRAWINGS

FIG. 1A, FIG. 1B, FIG. 1C, and FIG. 1D are sectional views schematically showing an example of magnetic recording medium manufacturing steps according to an embodiment;

FIG. 1E is a view showing FIG. 1A from above;

FIG. 1F is a view showing FIG. 1B from above;

FIG. 1G is a view showing FIG. 1C from above;

FIG. 1H is a view showing FIG. 1D from above;

FIG. 2 is an outline sectional view showing an example of a perpendicular magnetic recording medium according to an embodiment;

FIG. 3 is an outline sectional view showing an example of a perpendicular magnetic recording medium for comparison;

FIG. 4 is an outline sectional view showing an example of a perpendicular magnetic recording medium for comparison;

FIG. 5 is an outline sectional view showing an example of a perpendicular magnetic recording medium for comparison;

FIG. 6 is an outline sectional view showing an example of a perpendicular magnetic recording medium for comparison;

FIG. 7 is a schematic view showing a planar TEM image of an initial layer portion of a nonmagnetic interlayer of the perpendicular magnetic recording medium according to the embodiment;

FIG. 8 is an outline sectional view showing an example of a perpendicular magnetic recording medium for comparison;

FIG. 9 is an outline sectional view showing an example of a perpendicular magnetic recording medium for comparison;

FIG. 10 is an outline sectional view showing an example of a perpendicular magnetic recording medium for comparison;

FIG. 11 is an outline sectional view showing an example of a perpendicular magnetic recording medium for comparison;

FIG. 12 is an outline sectional view showing an example of a perpendicular magnetic recording medium for comparison;

FIG. 13 is an outline sectional view showing an example of a perpendicular magnetic recording medium for comparison;

FIG. 14 is an outline sectional view showing an example of a perpendicular magnetic recording medium for comparison; and

FIG. 15 is a partially exploded perspective view showing an example of a magnetic recording/reproduction apparatus according to an embodiment.

### DETAILED DESCRIPTION

In general, according to one embodiment, a perpendicular magnetic recording medium includes an SUL, orientation control layer, metal oxide posts, grain size control layer, and perpendicular magnetic recording layer formed in this order on a substrate. The orientation control layer mainly contains nickel having an fcc structure. A plurality of metal oxide posts having a pitch dispersion of 15% or less and the grain size control layer containing crystal grains grown to be higher than the metal oxide posts in a region defined by the metal oxide posts and having an hcp structure or the fcc structure are formed on the orientation control layer. The magnetic recording layer is formed on the metal oxide posts and grain size control layer.

The metal oxide posts used in the embodiment can mainly contain alumina.

The alumina posts can be obtained by forming, on the orientation control layer, an AlSi layer containing aluminum grains and a silicon grain boundary formed around the aluminum grains, and performing etching.

On the surface of the orientation control layer, a recess can be formed in a region except for a region where the alumina posts are formed.

In the perpendicular magnetic recording medium according to the embodiment, the grain size control layer having a good crystal orientation and low grain size dispersion is obtained by forming the plurality of metal oxide posts having a pitch dispersion of 15% or less. This makes it possible to improve the crystal orientation and grain size dispersion of magnetic grains to be formed on the grain size control layer.

A perpendicular magnetic recording medium manufacturing method according to the embodiment includes steps of

forming an SUL on a substrate,

forming an orientation control layer mainly containing nickel having the fcc structure on the SUL,

forming, on the orientation control layer, an aluminum silicon film containing aluminum grains and a silicon grain boundary formed around the aluminum grains,

forming alumina posts by oxidizing and removing the silicon grain boundary by etching the aluminum silicon film in an oxygen ambient and by oxidizing and etching the aluminum grains having an etching rate lower than that of the silicon grain boundary,

forming a grain size control layer by growing crystal grains having the hcp structure or fcc structure in a region defined by the alumina posts on the orientation control layer, and

forming a perpendicular magnetic recording layer on the grain size control layer.

The metal oxide posts used in the embodiment can have a height of 5 nm or less and a diameter of 5 nm or less.

If the height of the metal oxide posts exceeds 5 nm, sputtered particles having flown on the metal oxide posts cannot diffuse below the posts, so crystal grains are often formed on the metal oxide posts. Also, if the height is less than 1 nm, the metal oxide posts cannot function as posts because they are too low, so crystal grains are often formed on the metal oxide posts.

If the diameter of the metal oxide posts exceeds 5 nm, the filling ratio of crystal grains in the grain size control layer or perpendicular magnetic recording layer formed between the posts decreases, so the signal intensity of a recording signal decreases, and the SNR characteristic tends to worsen. Also, if the diameter is less than 1 nm, the strength of the posts decreases, and some posts break. Therefore, the metal oxide posts do not sufficiently function as posts, and the grain size dispersion of the crystal grains of the grain size control layer tends to worsen.

The aluminum silicon film can directly be formed on the orientation control layer.

The step of forming alumina posts can include oxidizing and removing the silicon grain boundary, and forming a surface oxide layer by oxidizing a region of the orientation control layer surface except for a region where the alumina posts are formed. The method can further include a step of removing the surface oxide layer before the step of forming a grain size control layer.

When an aluminum silicon film is etched in an oxygen ambient in the embodiment, the silicon grain boundary and aluminum grains are oxidized and etched. Since the etching rate of the silicon grain boundary is higher than that of the aluminum grains, the silicon grain boundary is etched faster than the aluminum grains. When etching is stopped when the silicon grain boundary is sufficiently removed by etching, some or most of the aluminum grains remain in the oxidized state, and form alumina posts. In this state, the region of the orientation control layer surface where the silicon grain boundary is formed is affected by etching in the oxygen ambient, and a surface oxide layer can be formed. By further etching this surface oxide layer, a recess can be formed in the region of the orientation control layer surface except for the region where the alumina posts are formed.

Since the above-described recess is further formed in the orientation control layer in the region defined by the alumina posts, the surface properties of the orientation control layer become uniform, and the product quality stabilizes. If the above-described recess is not formed, a portion where the silicon grain boundary is not completely etched but left behind may be formed. In this case, the grain size control layer is formed on the silicon grain boundary, and the crystal orientation of the grain size control layer and perpendicular magnetic recording layer worsens, and the SNR characteristic often deteriorates.

The orientation control layer and grain size control layer used in the embodiment can be brought into contact with each other.

The material of the grain size control layer used in the embodiment is Ru, or an alloy of Ru and at least one metal selected from the group consisting of Cr, Mo, Co, Mn, and Si.

Furthermore, the grain size control layer used in the embodiment can contain Ru as a main component.

Note that a “main component” herein mentioned is an element or element group having the highest component ratio among components forming a substance.

The orientation control layer can have the fcc structure, and can be made of Ni and at least one element selected from the group consisting of W, Cr, Mo, and V. The amount of metal to be added to Ni can be set at 5 to 30 at%. If the amount is less than 5 at%, the magnetism of Ni cannot be ignored any longer and behaves as magnetic noise, and the recording/reproduction characteristic often worsens. If the amount exceeds 30 at%, the Ni alloy cannot maintain the fcc structure any longer and changes into an amorphous structure, so the crystal orientation tends to deteriorate.

Also, the orientation control layer used in the embodiment can contain NiW as a main component.

Examples of the substrate usable in the embodiment are a glass substrate, an Al-based alloy substrate, a ceramic substrate, a carbon substrate, and an Si single-crystal substrate having an oxidized surface. Examples of the glass substrate are amorphous glass and crystallized glass. Examples of the amorphous glass are general-purpose soda-lime glass and aluminosilicate glass. An example of the crystallized glass is lithium-based crystallized glass. Examples of the ceramic substrate are general-purpose sintered products mainly containing aluminum oxide, aluminum nitride, and silicon nitride, and their fiber reinforced products. As the substrate, it is also possible to use a substrate obtained by forming a thin film such as an NiP layer by plating or sputtering on the surface of the metal substrate or nonmetal substrate described above. The method of forming the thin film on the substrate is not limited to sputtering, and the same effect can be obtained by using vacuum deposition or electroplating.

It is possible to further form an adhesive layer, SUL, or nonmagnetic underlayer between the nonmagnetic substrate and magnetic recording layer.

The adhesive layer is formed to improve the adhesion to the substrate. As the material of the adhesive layer, it is possible to use a material having an amorphous structure such as Ti, Ta, W, Cr, Pt, or an alloy, oxide, or nitride of any of these elements.

The adhesive layer can have a thickness of, e.g., 5 to 30 nm.

If the thickness is less than 5 nm, it is impossible to ensure sufficient adhesion, and film peeling readily occurs. If the thickness exceeds 30 nm, the process time prolongs, and the throughput tends to worsen.

The SUL horizontally passes a recording magnetic field from a single-pole head for magnetizing the perpendicular magnetic recording layer, and returns the magnetic field toward the magnetic head, i.e., performs a part of the function of the magnetic head. The SUL has a function of applying a steep sufficient perpendicular magnetic field to the magnetic field recording layer, thereby increasing the recording/reproduction efficiency. A material containing Co, Fe, or Ni can be used as the SUL. Examples of the material are Co alloys containing Co and at least one of Zr, Hf, Nb, Ta, Ti, and Y. The Co alloy can contain 80 at% or more of Co. When the Co alloy like this is deposited by sputtering, an amorphous layer readily forms. The amorphous soft magnetic material has none of magnetocrystalline anisotropy, a crystal defect, and a grain boundary, and hence has very high soft magnetism and can reduce the noise of the medium. Examples of the amorphous soft magnetic material are CoZr-, CoZrNb-, and CoZrTa-based alloys. Other examples of the SUL material are CoFe-based alloys such as CoFe and CoFeV, FeNi-based alloys such as FeNi, FeNiMo, FeNiCr, and FeNiSi, FeAl-based and FeSi-based alloys such as FeAl, FeAlSi, FeAlSiCr, FeAlSiTiRu, and FeAlO, FeTa-based alloys such as FeTa, FeTaC, and FeTaN, and FeZr-based alloys such as FeZrN. It is also possible to use a material having a microcrystalline structure or a granular structure in which fine crystal grains are dispersed in a matrix. Examples are FeAlO, FeMgO, FeTaN, and FeZrN containing 60 at% or more of Fe.

The SUL can have a thickness of, e.g., 10 to 100 nm.

If the thickness is less than 10 nm, it is often impossible to sufficiently receive a recording magnetic field from a magnetic head, and increase the recording/reproduction efficiency. If the thickness exceeds 100 nm, the process time prolongs, and the throughput tends to worsen.

Furthermore, in order to prevent spike noise, it is possible to divide the SUL into a plurality of layers, and insert a 0.5- to 1.5-nm thick nonmagnetic dividing layer, thereby causing antiferromagnetic coupling. As the nonmagnetic dividing layer, it is possible to use, e.g., Ru, an Ru alloy, Pd, Cu, or Pt. The SUL may also be exchange-coupled with a hard magnetic film having in-plane anisotropy such as CoCrPt, SmCo, or FePt, or a pinned layer made of an antiferromagnetic material such as IrMn or PtMn. To control the exchange coupling force, it is possible to stack magnetic films such as Co or nonmagnetic films such as Pt on the upper and lower surfaces of the nonmagnetic dividing layer.

The perpendicular magnetic recording layer usable in the embodiment can contain at least Co and Pt as main elements, and an oxide or Cr, B, Cu, Ta, Zr, or Ru can further be added for the purpose of, e.g., improving the SNR characteristic. Examples of the oxide to be contained in the perpendicular magnetic recording layer are SiO₂, SiO, Cr₂O₃, CoO, Co₃O₄, Ta₂O₅, and TiO₂. The content of this oxide can be set within the range of 7 to 15mol%. If the content of the oxide is less than 7 mol%, the division of the magnetic grains becomes insufficient, and the SNR characteristic often becomes insufficient. If the content of the oxide exceeds 15 mol%, it often becomes impossible to obtain a coercive force corresponding to a high recording density. The nuclear magnetism generation energy (−Hn) of the perpendicular magnetic recording layer can be set at 1.5 (kOe) or more. If the −Hn is less than 1.5 (kOe), a thermal decay often occurs.

The thickness of the magnetic recording layer can be set at 3 to 30 nm, and further can be set at 5 to 15 nm. When the thickness falls within this range, it is possible to manufacture a magnetic recording/reproduction apparatus more suitable for a high recording density. If the thickness of the magnetic recording layer is less than 3 nm, the reproduced output is too low, and the noise component often becomes higher. If the thickness of the magnetic recording layer exceeds 30 nm, the reproduced output often becomes too high and distorts the waveform. The magnetic recording layer can also be a multilayered film including two or more layers. In this case, the total thickness of the stacked layers can be set within the above-described range. The coercive force of the magnetic recording layer can be set to 3 kOe (237,000 A/m) or more. If the coercive force is less than 3 kOe, the thermal decay resistance tends to decrease. The perpendicular squareness ratio of the magnetic recording layer can be set at 0.8 or more. If the perpendicular squareness ratio is less than 0.8, the thermal decay resistance tends to decrease.

A protective layer can be formed on the perpendicular magnetic recording layer.

The protective layer prevents the corrosion of the perpendicular magnetic recording layer, and prevents damages to the medium surface when a magnetic head comes in contact with the medium. As the protective layer, a material containing C, SiO₂, or ZrO₂ can be used. The thickness of the protective layer can be set within the range of 1 to 10 nm. When the thickness of the protective layer falls within the range of 1 to 10 nm, the distance between a magnetic head and the medium can be decreased, and this is desirable for a high recording density. C can be classified into sp²-bonded carbon (graphite) and sp³-bonded carbon (diamond). Of amorphous carbons containing both sp²-bonded carbon and sp³-bonded carbon, diamond-like carbon (DLC) having a high sp³-bonded carbon ratio is useful in respect of the durability and corrosion resistance. DLC can be deposited by CVD (Chemical Vapor Deposition). In CVD, DLC is produced by a chemical reaction by exciting and decomposing a source gas in plasma.

In the granular type recording layer using Co, the Pt content in the magnetic recording layer can be set at 10 at% (inclusive) to 25 at% (inclusive). When the Pt content falls within the above range, a uniaxial magnetocrystalline anisotropy constant (Ku) necessary for the magnetic recording layer is obtained, and the crystal orientation of the magnetic grains improves. Consequently, thermal decay characteristics and recording/reproduction characteristics suited to high-density recording are often obtained. If the Pt content is larger or smaller than the above-mentioned range, it is often impossible to obtain a sufficient Ku necessary for thermal decay characteristics suited to high-density recording.

A magnetic recording/reproduction apparatus according to an embodiment includes the above-described perpendicular magnetic recording medium, a mechanism for supporting and rotating the perpendicular magnetic recording medium, a magnetic head including an element for recording information on the perpendicular magnetic recording medium and an element for reproducing recorded information, and a carriage assembly for supporting the magnetic head such that the magnetic head can freely move with respect to the perpendicular magnetic recording medium.

FIG. 15 is a partially exploded perspective view showing an example of the magnetic recording/reproduction apparatus according to the embodiment.

In a magnetic recording/reproduction apparatus 2000 according to the embodiment, a rigid magnetic disk 62 for recording information according to the embodiment is fitted on a spindle 63, and rotated at a predetermined rotational speed by a spindle motor (not shown). A slider 64, on which a magnetic head which accesses the magnetic disk 62 and records and reproduces information is mounted, is attached to the distal end of a suspension 65 made of a thin leaf spring. The suspension 65 is connected to one end of an arm 66 including a bobbin for holding a driving coil (not shown).

A voice coil motor 67 as a kind of a linear motor is formed at the other end of the arm 66. The voice coil motor 67 includes the driving coil (not shown) wound around the bobbin of the arm 66, and a magnetic circuit including a permanent magnet and counter yoke facing each other so as to sandwich the driving coil between them.

The arm 66 is held by ball bearings (not shown) formed in the two, upper and lower portions of a fixed shaft, and rotatably swung by the voice coil motor 67. That is, the voice coil motor 67 controls the position of the slider 64 on the magnetic disk 62.

Embodiments will be explained below with reference to the accompanying drawings.

### Example 1 & Comparative Examples 1-4

A nonmagnetic glass substrate 1 (amorphous substrate MEL7 manufactured by KONICA MINOLTA, diameter=2.5 inches) was placed in a deposition chamber of a DC magnetron sputtering apparatus (C-3010 manufactured by CANON ANELVA), and the deposition chamber was evacuated to an ultimate vacuum degree of 1×10⁻⁵ Pa.

10-nm thick Cr-25% Ti was formed as an adhesive layer 2 on the substrate 1 at DC 500 W by supplying Ar gas into the deposition chamber so that the gas pressure was 0.7 Pa. Then, 40-nm thick Co-20at% Fe-7at%Ta-5at%Zr was formed as a soft magnetic layer 3 at an Ar pressure of 0.7 Pa and DC 500 W. Subsequently, 5-nm thick Ni-5at%W was formed as an orientation control layer 4 at an Ar pressure of 0.7 Pa and DC 500 W.

Low-pitch-dispersion alumina posts 5 were formed on the orientation control layer 4.

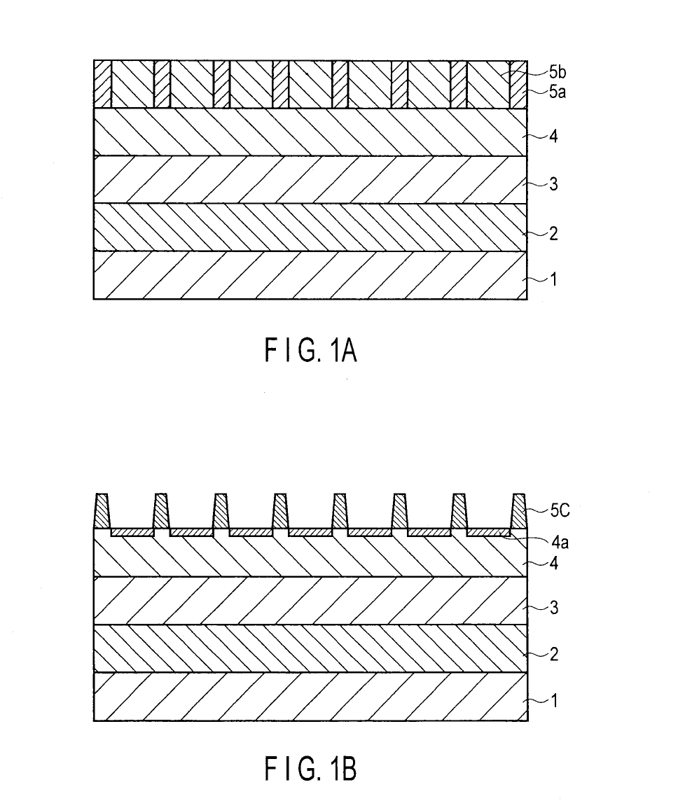

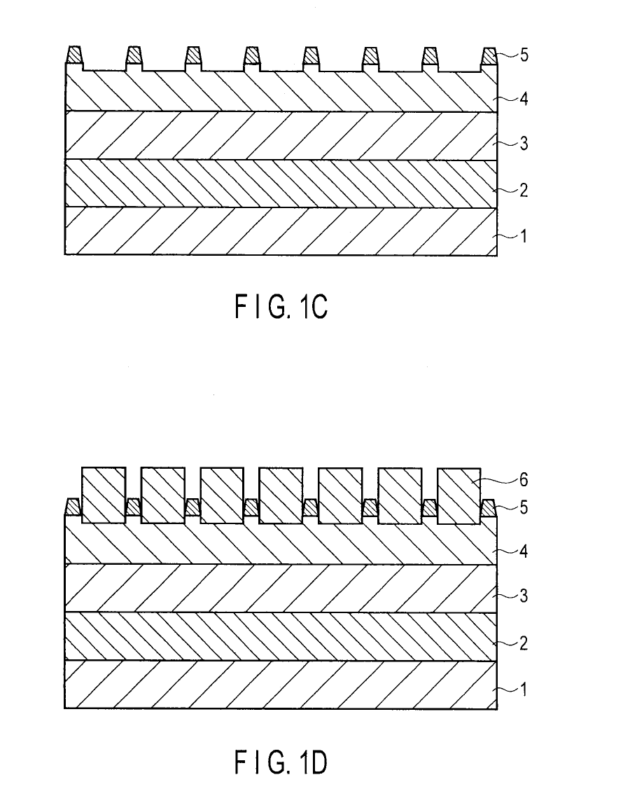

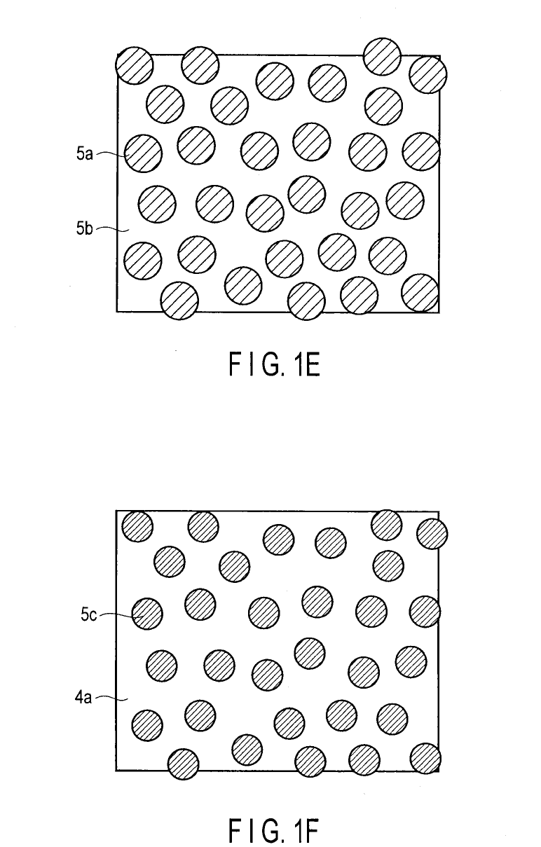

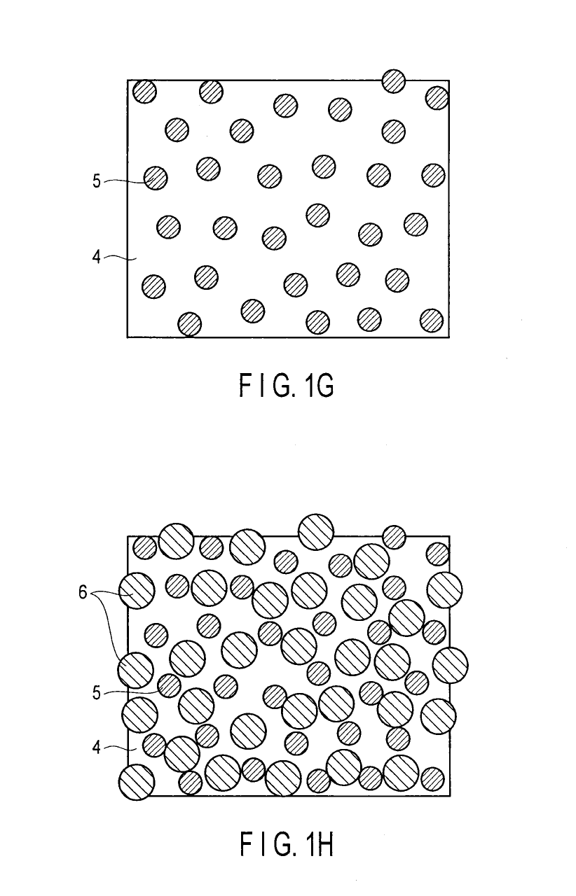

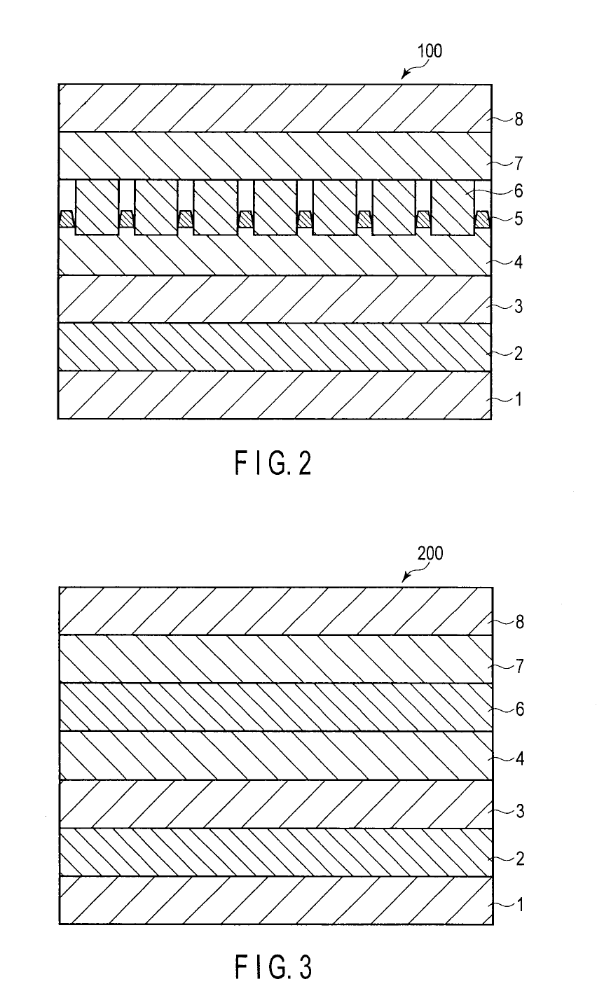

FIGS. 1A, 1B, 1C, 1D, and 2 are sectional views schematically showing examples of manufacturing steps of the magnetic recording medium according to the embodiment.

Also, FIGS. 1E, 1F, 1G, and 1H are respectively views showing the manufacturing steps shown in FIGS. 1A, 1B, 1C, and 1D from above.

First, as shown in FIGS. 1A and 1E, a 10-nm thick Al-50% Si film was formed as a low-pitch-dispersion film 5′ having a pitch dispersion of 15% or less on the orientation control layer 4 at an Ar pressure of 0.1 Pa and DC 100 W. The obtained low-pitch-dispersion Al—Si dispersion film 5′ included columnar Al grains 5a extending in a direction perpendicular to the substrate and having a diameter of 5 nmφ and an Si grain boundary 5b having a grain boundary width of 3 nm. Then, as shown in FIG. 1B, to form low-pitch-dispersion alumina posts 5, reverse sputtering was performed in an Ar—O₂ ambient obtained by adding 10% of O₂ gas to Ar gas. That is, Ar—O₂ gas was supplied so that the gas pressure was 2 Pa, and reverse sputtering was performed at RF 100 W, thereby oxidizing and etching the Al grains 5a and Si grain boundary 5b. Since the etching rate of Si is about twice that of Al, when the 10-nm thick Si grain boundary 5b was completely etched, the height of the 10-nm thick Al grains 5a was about 5 nm. Also, the Al grains 5a oxidized during the process of etching by Ar—O₂ and changed into alumina grains 5c. Since the circumferential surfaces of the grains were also etched, the shape of each grain was a circular truncated cone whose upper portion had a diameter of about 4 nmφ, as in FIGS. 1B and 1F. Since the Si grain boundary 5b disappeared, the NiW orientation control layer 4 was exposed, and the surface was oxidized by the oxygen gas, thereby forming an oxide layer 4a.

Subsequently, as shown in FIGS. 1C and 1G, the oxide layer 4a was etched by about 1 nm by changing the process gas to Ar gas. Consequently, the alumina grains 5c reduced the height to 4 nm, and changed into circular-truncated-cone-like alumina posts 5 whose upper portions had a diameter of about 3 nmφ. Also, the NiW orientation control layer 4 had a structure in which the region except for the alumina posts 5 recessed toward the substrate by about 1 nm compared to portions immediately below the alumina posts 5. However, the above-mentioned alumina post formation method is merely an example, and the alumina posts may also be formed by another method.

As shown in FIGS. 1D and 1H, 15-nm thick Ru was formed as a nonmagnetic interlayer 6 for controlling the grain size of magnetic grains of a perpendicular magnetic recording layer at an Ar pressure of 0.7 Pa and DC 500 W. After that, as shown in FIG. 2, 12-nm thick Co-18at%Pt-14at%Cr-10mol%SiO₂ was formed as a perpendicular magnetic recording layer 7 at an Ar pressure of 0.7 Pa and DC 500 W. Then, 2.5-nm thick diamond-like carbon (DLC) protective layer 8 was formed by CVD. Finally, the obtained structure was coated with a lubricating agent by dipping, thereby obtaining a perpendicular magnetic recording medium 100 according to the embodiment.

### Comparative Example 1

A perpendicular magnetic recording medium 200 according to Comparative Example 1 was obtained as shown in FIG. 3 following the same procedures as for the medium of Example 1, except that no Al-50% Si film was formed and no alumina posts 5 were formed by etching.

### Comparative Example 2

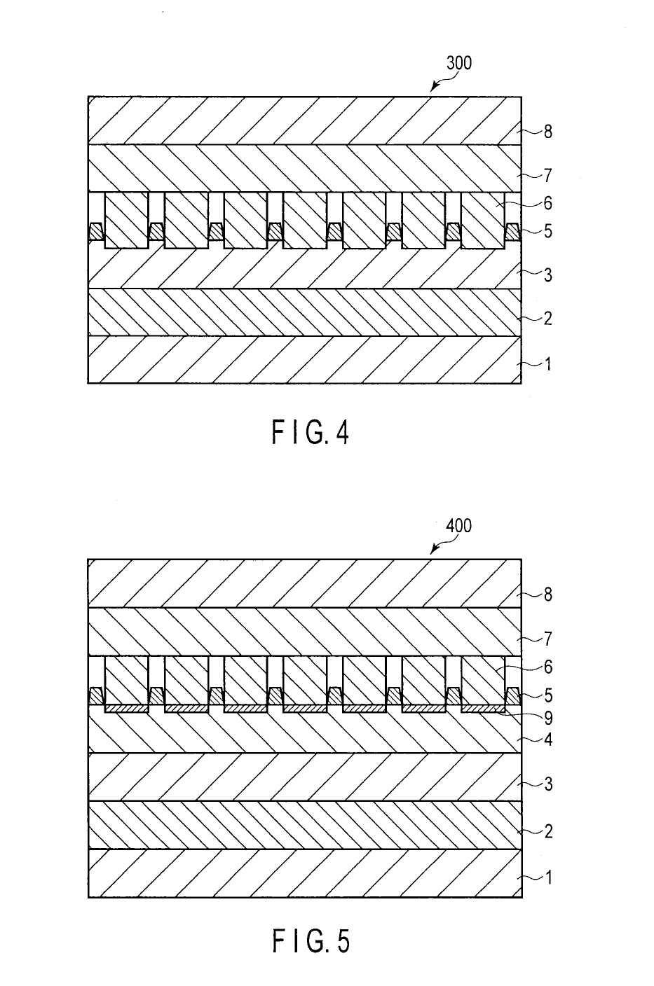

A perpendicular magnetic recording medium 300 according to Comparative Example 2 was obtained as shown in FIG. 4 following the same procedures as in Example 1, except that no NiW orientation control layer 4 was deposited.

### Comparative Example 3

A perpendicular magnetic recording medium 400 according to Comparative Example 3 was obtained as shown in FIG. 5 following the same procedures as for the medium of Example 1, except that after alumina posts 5 were formed, an oxidized NiW surface 9 in a region except for the alumina posts 5 was not etched by Ar gas.

### Comparative Example 4

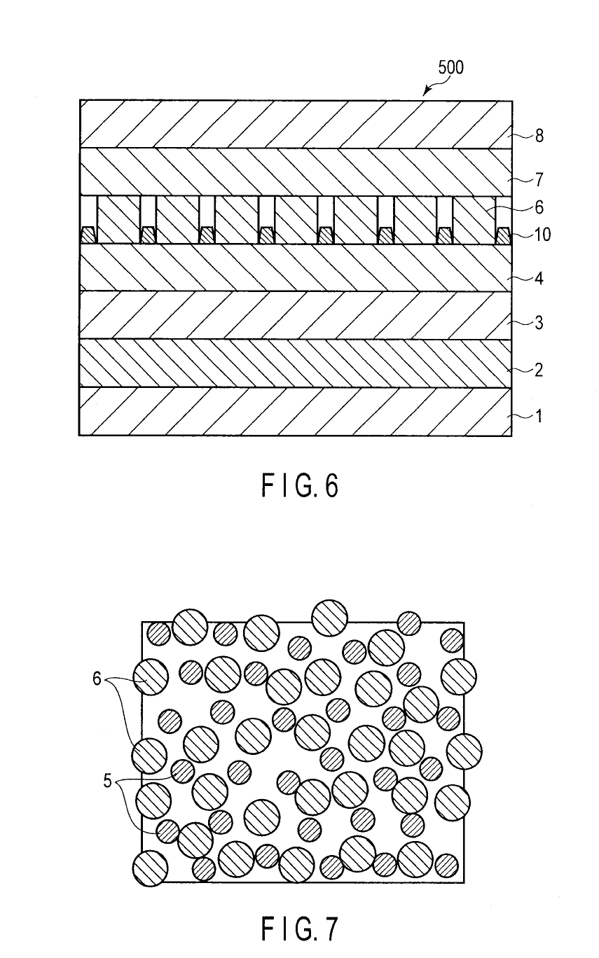

A perpendicular magnetic recording medium 500 according to Comparative Example 4 was obtained as shown in FIG. 6 following the same procedures as for the medium of Example 1, except that aluminum posts 10 were formed instead of alumina posts by using only Ar gas instead of Ar—O₂ gas when forming the posts, and neither a projection nor a recess was formed in the NiW orientation control layer.

The arrangements of the obtained perpendicular magnetic recording media will be summarized below.

### Arrangement of Example 1

Nonmagnetic glass substrate 1/CrTi adhesive layer 2/CoFeTaZr soft magnetic layer 3/Ni alloy orientation control layer 4/alumina posts 5+Ru nonmagnetic interlayer 6/CoCrPt—SiO₂ perpendicular magnetic recording layer 7/C protective layer 8

### Arrangement of Comparative Example 1

Nonmagnetic glass substrate 1/CrTi adhesive layer 2/CoFeTaZr soft magnetic layer 3/Ni alloy orientation control layer 4/Ru nonmagnetic interlayer 6/CoCrPt—SiO₂ perpendicular magnetic recording layer 7/C protective layer 8

### Arrangement of Comparative Example 2

Nonmagnetic glass substrate 1/CrTi adhesive layer 2/CoFeTaZr soft magnetic layer 3/alumina posts 5+Ru nonmagnetic interlayer 6/CoCrPt—SiO₂ perpendicular magnetic recording layer 7/C protective layer 8

### Arrangement of Comparative Example 3

Nonmagnetic glass substrate 1/CrTi adhesive layer 2/CoFeTaZr soft magnetic layer 3/Ni alloy orientation control layer (neither a projection nor a recess was formed, the surface was oxidized) 4/alumina posts 5+Ru nonmagnetic interlayer 6/CoCrPt—SiO₂ perpendicular magnetic recording layer 7/C protective layer 8

### Arrangement of Comparative Example 4

Nonmagnetic glass substrate 1/CrTi adhesive layer 2/CoFeTaZr soft magnetic layer 3/Ni alloy orientation control layer (neither a projection nor a recess was formed, the surface was not oxidized) 4/aluminum posts 10+Ru nonmagnetic interlayer 6/CoCrPt—SiO₂ perpendicular magnetic recording layer 7/C protective layer 8

The characteristics of the obtained media of Example 1 and Comparative Examples 1 to 4 were evaluated by analyzing them as follows.

First, the grain structures in the directions of a plane and section were observed by using transmission electron microscope (TEM) measurement.

Also, composition analysis was performed using energy dispersive X-ray spectroscopy (TEM-EDX). Consequently, in the medium of Example 1, alumina posts were formed into the shape of a gentle circular truncated cone having a height of 4 nm and a diameter of 3 nm on the NiW orientation control layer.

FIG. 7 is a schematic view showing a planar TEM image of an initial layer portion of the Ru nonmagnetic interlayer of the magnetic recording medium according to Example 1.

As shown in FIG. 7, about two to four alumina posts 5 were arranged around each Ru grain of the Ru nonmagnetic interlayer 6. The Ru grains had an average grain size of about 7 nm, and were formed between the alumina posts 5. Also, the sectional structure showed that the Ru grains 6 epitaxially grew from the NiW orientation control layer.

In the medium of Comparative Example 1, the NiW orientation control layer 4 and the Ru grains of the nonmagnetic interlayer 6 epitaxially grew, but the grain size of the Ru grains was 6 to 10 nm, i.e., the grain size dispersion was large.

In the medium of Comparative Example 2, the alumina posts 5 were directly formed on the soft magnetic layer 3. Also, the Ru grains were formed between the alumina posts 5, but the soft magnetic layer 3 and Ru grains did not epitaxially grow because the soft magnetic layer 3 had an amorphous structure. Furthermore, the lattice fringe of the Ru grains was random, so the crystal orientation was probably bad.

In the medium of Comparative Example 3, the alumina posts 5 were formed on the NiW orientation control layer 4. Also, the Ru grains were formed between the alumina posts 5, but the NiW orientation control layer 4 and Ru grains did not epitaxially grow because the surface layer portions of the NiW orientation control layer 4 immediately below the Ru grains (between the alumina posts) of the Ru nonmagnetic interlayer 6 had an amorphous structure. Furthermore, the lattice fringe of the Ru grains was random, so the crystal orientation was presumably bad.

In the medium of Comparative Example 4, the aluminum posts 5 were formed into the shape of a gentle circular truncated cone having a height of 4 nm and a diameter of 3 nm on the NiW orientation control layer 4. However, the Ru grains were formed not only between the aluminum posts 5 and but also on the aluminum posts 5, i.e., the Ru grains grew in directions other than the direction perpendicular to the substrate, thereby disturbing the columnar structure. This is so perhaps because no Ru grains were formed on the alumina posts 5 because the wettability between Ru and alumina was low, but the Ru grains were formed on the aluminum posts 5 because the wettability between Ru and aluminum was high.

Then, in the media of Example 1 and Comparative Examples 2 to 4, planar TEM observation was performed on the initial layer portion of the Ru nonmagnetic interlayer, and pitch analysis was performed not on the Ru grains but on the alumina posts and aluminum posts by using the planar TEM image. The difference between the Ru grain and alumina or aluminum post was discriminated by using EDX mapping. Consequently, both the alumina and aluminum posts had a pitch dispersion of about 13%, i.e., the pitch dispersion was low.

Subsequently, the grain structure in the direction of the plane of the perpendicular magnetic recording layer was observed using a planar TEM.

Also, composition analysis was performed using TEM-EDX, and the crystal orientation (Δθ50) of the perpendicular magnetic recording layer of each medium was checked by using an X-ray diffraction apparatus (XRD, Xpert-MRD available from Spectris).

Consequently, in the media of Example 1 and Comparative Examples 1 to 5, the crystal grains were made of crystalline CoCrPt, and the grain boundary was made of amorphous SiO₂.

The grain size of the perpendicular magnetic recording layer was then analyzed following the procedures below by using the results obtained by the planar TEM analysis.

First, from planar TEM images at magnifications of ×50 to ×2,000,000, an arbitrary image including at least 100 or more grains was input as image information to a computer. The contours of the individual crystal grains were extracted by performing image processing on this image information. Then, a diameter connecting two points on the circumference of the crystal grain and passing the barycenter was measured by a step of 2°, and the average value was measured as the crystal grain size of the crystal grain, thereby obtaining the average grain size and grain size dispersion. Also, the grain boundary width on a line connecting the barycenters of the grains was measured, and the average value was measured as the grain boundary width.

Table 1 (to be presented later) shows the results of the grain size analysis and crystal orientation of the media of Example 1 and Comparative Examples 1 to 4.

In the medium of Example 1, the average grain size was 6.7 nm, and the grain size dispersion was 13.4%, i.e., the results were good. Also, the crystal orientation Δθ50 of the perpendicular magnetic recording layer was as favorable as 2.8°. In the medium of Comparative Example 1, the average grain size of the perpendicular magnetic recording layer was 8 nm, i.e., larger than that of the medium of Example 1, and the grain size dispersion deteriorated to 22%. However, the Δθ50 of the perpendicular magnetic recording layer was 3.0°, i.e., the medium had a good crystal orientation almost equal to that of the medium of Example 1. The only difference between Example 1 and Comparative Example 1 was the presence/absence of the alumina posts. That is, the effect of the low-pitch-dispersion alumina posts implemented the perpendicular magnetic recording layer having the structure with a low grain size dispersion of 13.4% of the medium of Example 1. In the medium of Comparative Example 2, the average grain size was 7.3 nm, and the grain size dispersion was 15.3%, i.e., the characteristics were good. However, the crystal orientation was deteriorated to 11.7 deg. The crystal orientation worsened probably because the alumina posts suppressed the grain size dispersion of the Ru grains, but the Ru grains grew from the amorphous soft magnetic layer. In the medium of Comparative Example 3, the average grain size was 7.5 nm, and the grain size dispersion was 15.1%, i.e., the characteristics were good. However, the crystal orientation deteriorated to 12.5 deg. Similar to the medium of Comparative Example 2, the crystal orientation worsened presumably because the alumina posts suppressed the grain size dispersion of the Ru grains, but the Ru grains grew from the NiW surface that was oxidized and amorphousized. In the medium of Comparative Example 4, the average grain size was 7.6 nm, but the grain size dispersion largely deteriorated to 26.2%. This is so perhaps because the aluminum posts were used instead of alumina posts, so the Ru grains grew on the aluminum posts and disturbed the grain structure of the Ru interlayer.

Subsequently, the recording/reproduction characteristics of these media were evaluated. The evaluation of the recording/reproduction characteristics was performed by using read-write analyzer RWA1632 and spinstand S1701MP manufactured by GUZIK, U.S.A. The recording/reproduction characteristics were measured by using a head including a shielded magnetic pole as a single magnetic pole having a shield (a shield has a function of converging a magnetic flux generated from a magnetic head) for write, and a TMR element as a reproduction unit, and by setting the recording frequency condition at a linear recording density of 1,400 kBPI. Table 1 shows the results.

TABLE 1

| | | | | Perpendicular magnetic | | | |
|---|---|---|---|---|---|---|---|
| | | | | recording layer | | | |
| | | | | | Average | Grain size | |
| | | | Nonmagnetic | Δθ50 | grain size | dispersion | SNR |
| | Orientation control layer | Post | interlayer | (deg) | (nm) | (%) | (dB) |
| Example 1 | NiW | Al₂O₃ | Ru | 2.8 | 6.7 | 13.4 | 21.8 |
| Comparative | NiW | — | Ru | 3.0 | 8.0 | 22.0 | 17.8 |
| Example 1 | | | | | | | |
| Comparative | — | Al₂O₃ | Ru | 11.7 | 7.3 | 15.3 | 15.1 |
| Example 2 | | | | | | | |
| Comparative | NiW (neither projection | Al₂O₃ | Ru | 12.5 | 7.5 | 15.1 | 15.4 |
| Example 3 | nor recess was formed, | | | | | | |
| | surface was oxidized) | | | | | | |
| Comparative | NiW (neither projection | Al | Ru | 4.2 | 7.6 | 26.2 | 16.1 |
| Example 4 | nor recess was formed, | | | | | | |
| | surface was not oxidized) | | | | | | |

The medium according to Example 1 had an SNR of 21.8 dB, i.e., had a recording/reproduction characteristic better than those of the media of Comparative Examples 1 to 4.

In summary, in the medium of Example 1, the low-pitch-dispersion alumina posts formed on the NiW orientation control layer formed the low-grain-size-dispersion Ru grains, and made it possible to implement the low-grain-size-dispersion perpendicular magnetic recording layer. Also, a favorable crystal orientation was realized because the Ru nonmagnetic interlayer epitaxially grew from the NiW orientation control layer. This made the recording/reproduction characteristic better than those of the media of Comparative Examples 1 to 4. On the other hand, in the medium of Comparative Example 1, the grain size dispersion could not be improved because no alumina posts existed. Also, in the media of Comparative Examples 2 and 3, the crystal orientation of the perpendicular magnetic recording layer worsened because the orientation control layer of the Ru grains had an amorphous structure. In the medium of Comparative Example 4, the posts were made of aluminum instead of alumina, so the Ru grains probably grew on the posts and broken the grain structure of the Ru nonmagnetic interlayer.

According to the embodiment, a perpendicular magnetic recording medium having a low grain size dispersion can be obtained by using the low-pitch-dispersion alumina posts formed on the NiW orientation control layer, and growing the Ru grains of the interlayer made of an Ru alloy between the posts. This improves the crystallinity of the perpendicular magnetic recording layer while suppressing the grain size dispersion of the magnetic grains of the layer, thereby providing a magnetic recording medium having a good recording/reproduction characteristic with low medium transition noise.

### (2) Comparative Examples 5-13

Media of Comparative Examples 5 to 13 were manufactured as follows.

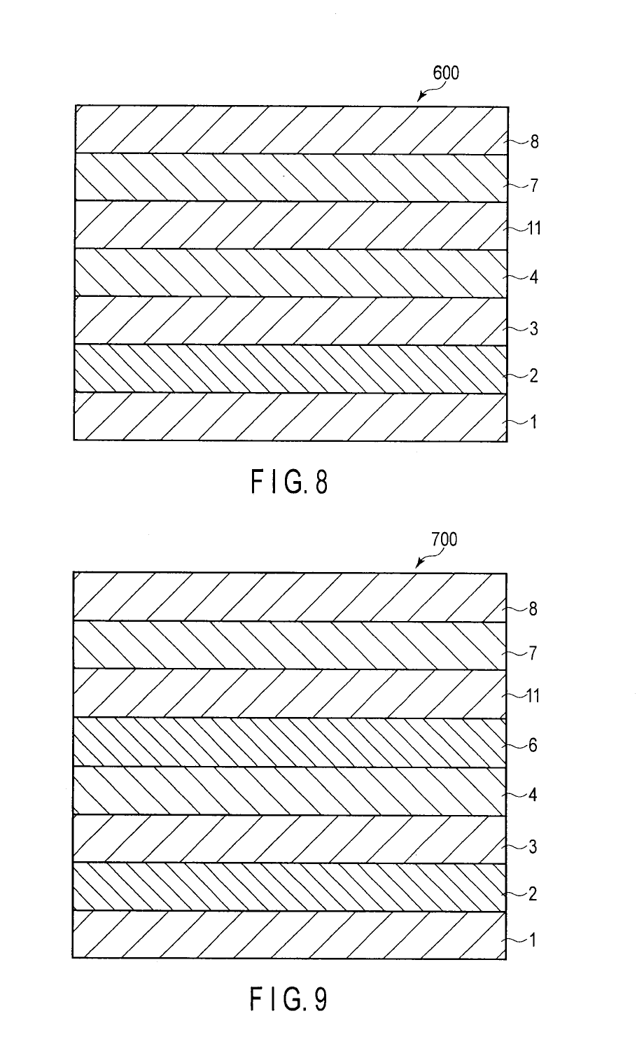

Perpendicular magnetic recording media 600 according to Comparative Examples 5 to 9 were obtained as shown in FIG. 8 following the same procedures as for the medium of Example 1, except that Ni-based compounds as shown in Table 2 below were used instead of the NiW orientation control layer, and an Ru-20mol%Al₂O₃ nonmagnetic interlayer 11 having a granular structure separated into Ru grains and an Al₂O₃ grain boundary was formed instead of the Ru interlayer including the alumina posts 5′.

Also, perpendicular magnetic recording media 700 according to Comparative Examples 10 and 11 were obtained as shown in FIG. 9 following the same procedures as for the medium of Example 1, except that Ni-based compounds as shown in Table 2 below were used instead of the NiW orientation control layer, and an Ru interlayer 6 and Ru-20mol%Al₂O₃ nonmagnetic layer 11 were stacked in this order instead of the Ru interlayer including the alumina posts 5′.

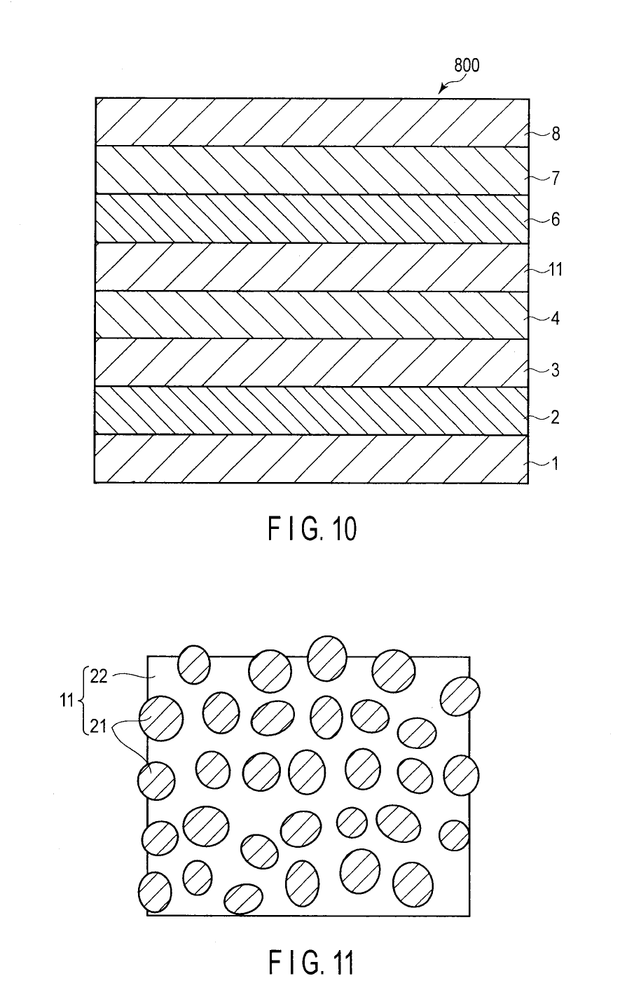

In addition, perpendicular magnetic recording media 800 according to Comparative Examples 12 and 13 were obtained as shown in FIG. 10 following the same procedures as for the medium of Example 1, except that Ni-based compounds as shown in Table 2 below were used instead of the NiW orientation control layer, and an Ru-20mol%Al₂O₃ nonmagnetic layer 11 and Ru interlayer 6 were stacked in this order instead of the Ru interlayer including the alumina posts 5′.

TABLE 2

| | | | | Perpendicular magnetic | | | |
|---|---|---|---|---|---|---|---|
| | | | | recording layer | | | |
| | | | | | Average | Grain size | |
| | | | Nonmagnetic | Δθ50 | grain size | dispersion | SNR |
| | Orientation control layer | Post | interlayer | (deg) | (nm) | (%) | (dB) |
| Example 1 | NiW | Al2O3 | Ru | 2.8 | 6.7 | 13.4 | 21.8 |
| Comparative | NiW | — | Ru—Al₂O₃ | 9.0 | 5.5 | 27.1 | 16.8 |
| Example 5 | | | | | | | |
| Comparative | Ni—50 at % Al | — | Ru—Al₂O₃ | 9.5 | 5.3 | 27.3 | 16.3 |
| Example 6 | (B2 structure) | | | | | | |
| Comparative | Ni—50 at % Ti | — | Ru—Al₂O₃ | 9.7 | 5.2 | 27.4 | 16.2 |
| Example 7 | (B2 structure) | | | | | | |
| Comparative | Ni—20% Fe (fcc structure, | — | Ru—Al₂O₃ | 9.2 | 5.7 | 27.2 | 16.5 |
| Example 8 | soft magnetism) | | | | | | |
| Comparative | NiFeNbMo (fcc structure, | — | Ru—Al₂O₃ | 9.3 | 5.8 | 27.2 | 16.5 |
| Example 9 | soft magnetism) | | | | | | |
| Comparative | NiW | — | Ru/Ru—Al₂O₃ | 6.3 | 5.5 | 24.3 | 17.5 |
| Example 10 | | | | | | | |
| Comparative | NiFeNbMo (fcc structure, | — | Ru/Ru—Al₂O₃ | 6.8 | 5.8 | 24.5 | 17.4 |
| Example 11 | soft magnetism) | | | | | | |
| Comparative | NiW | — | Ru—Al₂O₃/Ru | 7.2 | 5.5 | 25.4 | 17.2 |
| Example 12 | | | | | | | |
| Comparative | NiFeNbMo (fcc structure, | — | Ru—Al₂O₃/Ru | 7.5 | 5.8 | 25.7 | 17.0 |
| Example 13 | soft magnetism) | | | | | | |

The arrangements of the obtained perpendicular magnetic recording media will be summarized below.

### Arrangement of Comparative Examples 5 to 9

Nonmagnetic glass substrate 1/CrTi adhesive layer 2/CoFeTaZr soft magnetic layer 3/Ni alloy orientation control layer 4/Ru—Al₂O₃ nonmagnetic interlayer (granular structure) 11/CoCrPt—SiO₂ perpendicular magnetic recording layer 7/C protective layer 8

### Arrangement of Comparative Examples 10 and 11

Nonmagnetic glass substrate 1/CrTi adhesive layer 2/CoFeTaZr soft magnetic layer 3/NiW alloy or NiFeNbMo alloy orientation control layer 4/Ru nonmagnetic interlayer 6/Ru—Al₂O₃ nonmagnetic interlayer (granular structure) 11/CoCrPt—SiO₂ perpendicular magnetic recording layer 7/C protective layer 8

### Arrangement of Comparative Examples 12 and 13

Nonmagnetic glass substrate 1/CrTi adhesive layer 2/CoFeTaZr soft magnetic layer 3/NiW alloy orientation control layer 4/Ru—Al₂O₃ nonmagnetic interlayer (granular structure) 11/Ru nonmagnetic interlayer 6/CoCrPt—SiO₂ perpendicular magnetic recording layer 7/C protective layer 8

The grain structures in the directions of a plane and section of the media of these comparative examples were observed by using TEM measurement.

Also, composition analysis was performed using TEM-EDX.

FIG. 11 is a schematic view showing a planar TEM image of an initial layer portion of the Ru—Al₂O₃ interlayer of each of the media of Comparative Examples 5 to 13.

As shown in FIG. 11, Al₂O₃ 22 was formed to surround Ru grains 21, so an Ru—Al₂O₃ nonmagnetic interlayer 11 had a so-called granular structure. That is, the structure of the nonmagnetic interlayer 11 of each of the media of Comparative Examples 5 to 13 was entirely different from that of the nonmagnetic interlayer 6 of the medium of Example 1 shown in FIG. 7. Also, the average grain size of the Ru grains was 5 to 6 nm, i.e., smaller than 7 nm as the average grain size of the Ru grains of the medium of Example 1.

In the media of Comparative Examples 5 to 13, the average grain size of the perpendicular magnetic recording layer was as small as 5 to 6 nm, but the grain size dispersion deteriorated to 24% to 28%. In addition, the crystal orientation deteriorated to 6 to 10 deg. That is, in the media of Comparative Examples 5 to 13, the Ru (grain)-Al₂O₃ (grain boundary) layer having the granular structure or the multilayered structure of the Ru—Al₂O₃ layer and Ru layer was used instead of forming the alumina posts of the Ru nonmagnetic interlayer. However, the Ru—Al₂O₃ layer having the granular structure had a function of decreasing the grain size, but worsened the grain size dispersion and crystal orientation.

The crystal orientation, the average grain size and grain size dispersion of the perpendicular magnetic recording layer, and the recording/reproduction characteristic of each of these media were checked in the same manner as in Example 1. As shown in Table 2, the medium of Example 1 improved in the crystal orientation (Δθ₅₀) and grain size dispersion of the perpendicular magnetic recording layer, and hence improved in the recording/reproduction characteristic, when compared to the media of Comparative Examples 5 to 13.

### (3) Examples 2-4 & Comparative Examples 14-16

### Arrangement of Examples 2 to 4 and Comparative Examples 14 to 16

Nonmagnetic glass substrate 1/CrTi adhesive layer 2/CoFeTaZr soft magnetic layer 3/Ni alloy orientation control layer 4/alumina posts 5+Ru nonmagnetic interlayer 6/CoCrPt—SiO₂ perpendicular magnetic recording layer 7/C protective layer 8

Perpendicular magnetic recording media 100 according to Examples 2 to 4 and Comparative Examples 14 to 16 were obtained following the same procedures as for the medium of Example 1, except that the alumina post height was changed from 0.5 to 10 nm as shown in Table 3 (to be presented later) by changing the process time and the like of alumina post formation. The diameters of the alumina posts were approximately 2 to 4 nm.

The grain structures in the directions of a plane and section of the media of these comparative examples were observed by using TEM measurement.

Also, composition analysis was performed using TEM-EDX. Consequently, the Ru grains were also formed on the posts in the nonmagnetic interlayer of the medium of Comparative Example 14. This is so probably because the wettability between Ru and alumina is low, so the nuclei of the Ru grains were generated between the alumina posts, but the alumina posts did not function as posts for restricting the growth of the Ru grains in the lateral direction because the alumina post height was as low as 0.5 nm, and the Ru grains spread onto the alumina posts.

In the nonmagnetic interlayer of each of the media of Examples 2 to 4, alumina posts were formed into the shape of a gentle circular truncated cone having a height of 4 nm and a diameter of 3 nm on the NiW orientation control layer, as in Example 1. Ru grains were formed between the alumina posts, and the sectional structure showed that the Ru grains epitaxially grew from the NiW orientation control layer. In the nonmagnetic interlayers of the media of Comparative Examples 15 and 16, the Ru grains were nonuniformly formed on the alumina posts. This is presumably because the alumina posts were too high, so Ru atoms that flew onto the alumina posts during sputtering could not leave the alumina posts but stayed on the alumina posts, thereby generating the nuclei of the Ru grains.

The crystal orientation, the average grain size and grain size dispersion of the perpendicular magnetic recording layer, and the recording/reproduction characteristic of each of these media were checked following the same procedures as in Example 1.

Table 3 below shows the obtained results.

TABLE 3

| | | Perpendicular magnetic | | | |
|---|---|---|---|---|---|
| | | recording layer | | | |
| | Alumina | | Average | Grain size | |
| | post height | Δθ50 | grain size | dispersion | SNR |
| | (nm) | (deg) | (nm) | (%) | (dB) |
| Comparative | 0.5 | 4.0 | 7.9 | 23.4 | 17.5 |
| Example 14 | | | | | |
| Example 2 | 1 | 2.6 | 6.7 | 14.5 | 21.3 |
| Example 3 | 2 | 2.7 | 6.7 | 14.0 | 21.5 |
| Example 1 | 3 | 2.8 | 6.7 | 13.4 | 21.8 |
| Example 4 | 5 | 2.9 | 6.7 | 13.1 | 21.6 |
| Comparative | 8 | 5.8 | 7.5 | 21.1 | 17.6 |
| Example 15 | | | | | |
| Comparative | 10 | 7.2 | 7.8 | 23.6 | 16.2 |
| Example 16 | | | | | |

As shown in Table 3, the recording/reproduction characteristics of the media of Example 1 to 4 were better than those of the media of Comparative Examples 14 to 16.

### (4) Comparative Examples 17-19

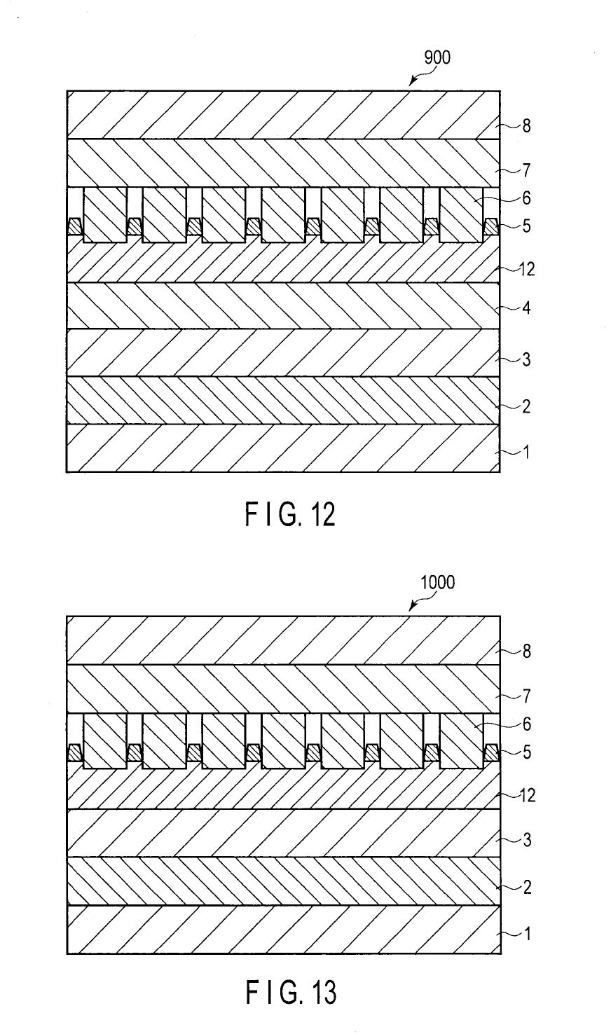

A perpendicular magnetic recording medium 900 according to Comparative Example 17 was obtained as shown in FIG. 12 following the same procedures as for the medium of Example 1, except that a Ta underlayer was formed between the NiW orientation control layer and the Ru nonmagnetic interlayer including the alumina posts.

A perpendicular magnetic recording medium 1000 according to Comparative Example 18 was obtained as shown in FIG. 13 following the same procedures as for the medium of Example 1, except that a Ta underlayer was formed instead of the NiW orientation control layer.

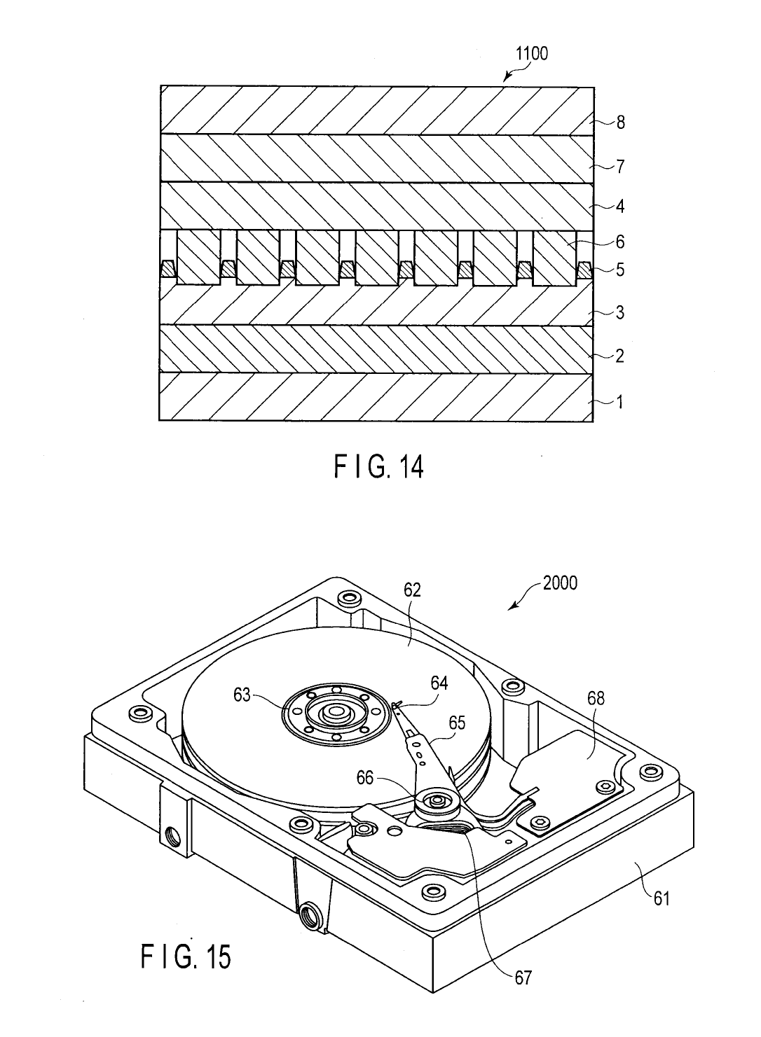

A perpendicular magnetic recording medium 1100 according to Comparative Example 19 was obtained as shown in FIG. 14 following the same procedures as for the medium of Example 1, except that the formation order of the NiW orientation control layer and the Ru nonmagnetic interlayer including the alumina posts was reversed.

### Arrangement of Comparative Example 17

Nonmagnetic glass substrate 1/CrTi adhesive layer 2/CoFeTaZr soft magnetic layer 3/NiW alloy orientation control layer 4/Ta underlayer 12/alumina posts 5+Ru nonmagnetic interlayer 6/CoCrPt—SiO₂ perpendicular magnetic recording layer 7/C protective layer 8

### Arrangement of Comparative Example 18

Nonmagnetic glass substrate 1/CrTi adhesive layer 2/CoFeTaZr soft magnetic layer 3/Ta underlayer 12/alumina posts 5+Ru nonmagnetic interlayer 6/CoCrPt—SiO₂ perpendicular magnetic recording layer 7/C protective layer 8

### Arrangement of Comparative Example 19

Nonmagnetic glass substrate 1/CrTi adhesive layer 2/CoFeTaZr soft magnetic layer 3/alumina posts 5+Ru nonmagnetic interlayer 6/NiW alloy orientation control layer 4/CoCrPt—SiO₂ perpendicular magnetic recording layer 7/C protective layer 8

The crystal orientation, the average grain size and grain size dispersion of the perpendicular magnetic recording layer, and the recording/reproduction characteristic of each of these media were checked following the same procedures as in Example 1.

Table 4 below shows the obtained results.

TABLE 4

| | | Perpendicular magnetic | | | |
|---|---|---|---|---|---|
| | | recording layer | | | |
| | | | Average | Grain | |
| | | | grain | size dis- | |
| | | Δθ50 | size | persion | SNR |
| | Film arrangement | (deg) | (nm) | (%) | (dB) |
| Example 1 | NiW orientation control | 2.8 | 6.7 | 13.4 | 21.8 |
| | layer/Ru + alumina post | | | | |
| | nonmagnetic interlayer | | | | |
| Comparative | NiW orientation control | 5.2 | 5.5 | 18.1 | 18.8 |
| Example 17 | layer/Ta underlayer/Ru + | | | | |
| | alumina post nonmagnet- | | | | |
| | ic interlayer | | | | |
| Comparative | Ta underlayer/Ru + | 5.4 | 5.8 | 18.6 | 18.4 |
| Example 18 | alumina post nonmagnet- | | | | |
| | ic interlayer | | | | |
| Comparative | Ru + alumina post | 14.3 | 12.3 | 26.6 | 9.3 |
| Example 19 | nonmagnetic interlayer/ | | | | |
| | NiW orientation control | | | | |
| | layer | | | | |

As shown in Table 4, the recording/reproduction characteristics of the media of Comparative Examples 17 to 19 were worse than that of the medium of Example 1.

This is perhaps because in the media of Comparative Examples 17 and 18, the Ta underlayer had a bcc structure close to an amorphous structure, so the crystal orientation of the perpendicular magnetic recording layer became worse than that of the medium of Example 1, and the recording/reproduction characteristic also deteriorated. This is also presumably because when the NiW orientation control layer and Ru nonmagnetic interlayer were switched, the crystallinity, average grain size, and grain size dispersion of the perpendicular magnetic recording layer largely worsened, and as a consequence the recording/reproduction characteristic largely deteriorated.

### (5) Examples 5-8

### Arrangement of Examples 5 to 8

Nonmagnetic glass substrate 1/CrTi adhesive layer 2/CoFeTaZr soft magnetic layer 3/Ni alloy orientation control layer 4/alumina posts 5+Ru nonmagnetic interlayer 6/CoCrPt—SiO₂ perpendicular magnetic recording layer 7/C protective layer 8

Perpendicular magnetic recording media 100 according to Examples 5 to 8 were obtained following the same procedures as for the medium of Example 1, except that Ni alloys as shown in Table 5 below were used as the orientation control layer.

The crystal orientation, the average grain size and grain size dispersion of the perpendicular magnetic recording layer, and the recording/reproduction characteristic of each of these media were checked following the same procedures as in Example 1.

Table 5 below shows the obtained results.

TABLE 5

| | | Perpendicular magnetic | | | |
|---|---|---|---|---|---|
| | | recording layer | | | |
| | | | Average | Grain size | |
| | Orientation | Δθ50 | grain size | dispersion | SNR |
| | control layer | (deg) | (nm) | (%) | (dB) |
| Example 1 | Ni-5 at % W | 2.8 | 6.7 | 13.4 | 21.8 |
| Example 5 | Ni-5 at % Cr | 2.8 | 6.7 | 13.4 | 21.8 |
| Example 6 | Ni-10 at % Cr | 2.9 | 6.7 | 13.4 | 21.7 |
| Example 7 | Ni-5 at % Mo | 3 | 6.7 | 13.4 | 21.6 |
| Example 8 | Ni-5 at % V | 3.1 | 6.7 | 13.4 | 21.6 |

As shown in Table 5, the media of Examples 5 to 8 had characteristics equal to those of the medium of Example 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A perpendicular magnetic recording medium comprising:
a substrate;
a soft underlayer formed on the substrate;
an orientation control layer formed on the soft underlayer and mainly containing nickel having a face-centered cubic structure;
a grain size control layer including a plurality of metal oxide posts formed on the orientation control layer and having a pitch dispersion of not more than 15%, and crystal grains having grown in a region defined by the plurality of metal oxide posts, and having a hexagonal close-packed structure or the face-centered cubic structure; and
a perpendicular magnetic recording layer formed on the grain size control layer.

2. The medium according to claim 1, wherein the metal oxide posts have a height of not more than 5 nm and a diameter of not more than 5 nm.

3. The medium according to claim 1, wherein the orientation control layer and the grain size control layer are in contact with each other.

4. The medium according to claim 1, wherein the orientation control layer mainly contains a nickel-tungsten alloy.

5. The medium according to claim 1, wherein the grain size control layer mainly contains ruthenium.

6. The medium according to claim 1, wherein the metal oxide posts mainly contain alumina.

7. The medium according to claim 6, wherein the metal oxide posts are formed by forming an AlSi layer on the orientation control layer and performing etching.

8. The medium according to claim 1, wherein a recess is formed in a region of a surface of the orientation control layer except for a region where the metal oxide posts are formed.

9. A perpendicular magnetic recording medium manufacturing method comprising:
forming a soft underlayer on a substrate;
forming, on the soft underlayer, an orientation control layer mainly containing nickel having a face-centered cubic structure;
forming, on the orientation control layer, an aluminum silicon film containing aluminum grains and a silicon grain boundary formed around the aluminum grains;
forming alumina posts by oxidizing and removing the silicon grain boundary by etching the aluminum silicon film in an oxygen ambient and by oxidizing and etching the aluminum grains having an etching rate lower than that of the silicon grain boundary;
forming a grain size control layer by growing crystal grains having a hexagonal close-packed structure or a face-centered cubic structure in a region defined by the alumina posts on the orientation control layer; and
forming a perpendicular magnetic recording layer on the grain size control layer.

10. The method according to claim 9, wherein
the forming the alumina posts includes oxidizing and removing the silicon grain boundary, and forming a surface oxide layer by oxidizing a region of a surface of the orientation control layer except for a region where the alumina posts are formed, and
the method further comprises removing the surface oxide layer before the forming the grain control layer.

11. A magnetic recording/reproduction apparatus comprising:
a perpendicular magnetic recording medium including a substrate, a soft underlayer formed on the substrate, an orientation control layer formed on the soft underlayer and mainly containing nickel having a face-centered cubic structure, a grain size control layer including a plurality of metal oxide posts formed on the orientation control layer and having a pitch dispersion of not more than 15%, and crystal grains having grown in a region defined by the plurality of metal oxide posts, and having a hexagonal close-packed structure or the face-centered cubic structure, and a perpendicular magnetic recording layer formed on the grain size control layer;
a mechanism configured to support and rotate the perpendicular magnetic recording medium;
a magnetic head including an element which records information on the perpendicular magnetic recording medium, and an element which reproduces recorded information; and
a carriage assembly configured to support the magnetic head such that the magnetic head freely moves with respect to the perpendicular magnetic recording medium.

12. The apparatus according to claim 11, wherein
the metal oxide posts have a height of not more than 5 nm and a diameter of not more than 5 nm.

13. The apparatus according to claim 11, wherein the orientation control layer and the grain size control layer are in contact with each other.

14. The apparatus according to claim 11, wherein the orientation control layer mainly contains a nickel-tungsten alloy.

15. The apparatus according to claim 11, wherein the grain size control layer mainly contains ruthenium.

16. The apparatus according to claim 11, wherein the metal oxide posts mainly contain alumina.

17. The apparatus according to claim 16, wherein the metal oxide posts are formed by forming an AlSi layer on the orientation control layer and performing etching.

18. The apparatus according to claim 11, wherein a recess is formed in a region of a surface of the orientation control layer except for a region where the metal oxide posts are formed.

19. The medium according to claim 2, wherein the orientation control layer mainly contains a nickel-tungsten alloy.

20. The medium according to claim 3, wherein the orientation control layer mainly contains a nickel-tungsten alloy.
